(19) United States
(12) Patent Application Publication
(10) Pub. No.: US 2024/0420862 A1
(43) Pub. Date: Dec. 19, 2024

(54) METHODS AND SYSTEMS FOR PHASE GATES IN QUANTUM COMPUTERS

(71) Applicant: Universal Quantum Ltd, Brighton (GB)

(72) Inventors: Zak David ROMASZKO, Brighton (GB); Peter BRADBEER, Brighton (GB)

(21) Appl. No.: 18/424,564

(22) Filed: Jan. 26, 2024

Related U.S. Application Data
(63) Continuation of application No. PCT/GB2022/052016, filed on Jul. 29, 2022.

(30) Foreign Application Priority Data
Jul. 30, 2021 (GB) GB 2111032.5

(51) Int. Cl. G21K 1/00; G06N 10/40

(52) U.S. Cl. CPC G21K 1/003; G06N 10/40

(57) ABSTRACT

A device comprising a plurality of independent rotation gates, each rotation gate comprising a magnet configured to generate a magnetic field of predetermined strength at a qubit position for the respective rotation gate. The magnetic field is configured to generate a resonant frequency in qubits at the qubit position due to magnetically sensitive electronic states of the qubit. The device further comprises a first electromagnetic field source configured to generate an electromagnetic field at the resonant frequency for a predetermined period across the plurality of independent rotation gates. Each independent rotation gate comprises a controller configured to independently move the qubit at the respective independent rotation gate out of resonance at a predetermined time within the predetermined period.

### CROSS-REFERENCE

This application is a continuation of International Application PCT/GB2022/052016, filed Jul. 29, 2022, which claims the benefit of GB Application No. 2111032.5, filed on Jul. 30, 2021, which applications are each incorporated herein by reference in their entireties.

### FIELD

The present invention relates to improvements in or relating to quantum computing, and in particular, to achieving site-specific gate control for magnetically sensitive qubits.

### BACKGROUND

Quantum computing in general, unlike so-called “classical computing”, relies on the quantum mechanical properties of particles or matter to produce or alter data. The data may be represented by quantum bits or “qubits”, which is a two state quantum mechanical system. Unlike classical computing, the qubit may be in superposition of quantum states. Another feature of quantum computing is the entanglement between qubits in which the state of one particle or atom is influenced by another particle or atom.

Quantum mechanical qubits are able to encode information as combinations of zeros and ones simultaneously. Such properties open numerous complex numerical applications that are traditionally difficult for classical computers. Examples include artificial Intelligence, image processing and recognition, cryptography, or secure communications and so on.

Within an ion hyperfine electronic states (Zeeman split states) can be revealed by the use of a magnetic field and the different electron levels used as the different qubit states and electrons moved between the levels using microwave radiation or lasers.

In ion trap quantum computers surface ion traps are used to control ions used in quantum computation and surface electrodes are used to generate electric fields to manipulate and trap the ions suspended in free space. The surface electrode potentials of an ion-trap are in turn controlled by DACs. The surface electrodes generate electric fields which can be used to move the ions around.

### SUMMARY

In quantum computers different channels are used to address different qubits. These channels can take the form of different resonant frequencies which, for magnetically sensitive qubits, such as ions can be generated using different magnetic fields and gradients.

However, as there is only a limited range of magnetic field which can be used before the Zeeman states begin splitting asymmetrically. There are therefore only a limited number of channels which can be globally supported by using different channels. When there are only a limited number of gates, and gates with fixed parameters this is not a problem because the fixed parameters can be applied to all qubits in a particular channel.

However, there are some gates which require variable parameters at different sites. An example of a gate with a variable parameter is an rotation gate in which the rotation of the qubit is a parameter in the gate. For these gates different rotations may be used for each gate. This is problematic because each different parameter requires a different channel. Given that the number of channels in a device is limited this limits the number of gates that can occur simultaneously. As a result, the runtime for such an arrangement is considerably lengthened.

Rotation gates require an arbitrary rotation of the qubit which can be applied. For magnetically sensitive qubits rotation can be applied using an electromagnetic field.

It is against this background that the present invention has arisen.

According to the invention there is provided a device comprising a plurality of independent rotation gates, each independent rotation gate comprising a magnet configured to generate a magnetic field of predetermined strength at a qubit position for the respective independent rotation gate, the magnetic field being configured to set a resonant frequency in a qubit at the qubit position due to magnetically sensitive electronic states of the qubit. The device further comprises a first electromagnetic field source configured to generate an electromagnetic field at the resonant frequency for a predetermined period across the plurality of independent rotation gates and wherein each independent rotation gate comprises a controller configured to independently move the qubit at the respective independent rotation gate out of resonance at a predetermined time within the predetermined period.

The rotation applied is around the x or y axis, where the z axis is parallel to the magnetic field generated by the magnet. The relative rotation axis between one electromagnetic pulse generated by the electromagnetic field source and another electromagnetic pulse can be changed by adjusting the pulse phase. For example, if a first electromagnetic pulse it at a first time, and a second electromagnetic pulse is at a second time (a multiple of) π/2 later, the first electromagnetic pulse would control rotation around one of the axes (for example the x axis) and the second electromagnetic pulse would control rotation around the other axis (for example the y axis.

Moving the qubit out of resonance may comprise moving the qubit so that it is in a different magnetic field or it may comprise changing the magnetic field so that the qubit is resonant at a different frequency.

There could be a single larger magnetic structure which forms the magnet for each independent rotation gate and generates the magnetic field of predetermined strength at a qubit position for each respective independent rotation gate.

One, or each independent rotation gate may further comprise a magnetic switch configured to adjust the magnetic field at the qubit position and moving the qubit out of resonance comprises switching the magnetic switch. Thus, during the predetermined period the magnetic field at the qubit position is changed such that the resonant frequency of the qubit changes and the qubit is no longer sensitive to the electromagnetic field.

The combined magnetic field of predetermined strength and the magnetic field generates a second resonant frequency and the device further comprises a second electromagnetic field source configured to generate an electromagnetic field at the second resonant frequency. Thus, the qubit may be moved from a first resonant frequency to a second resonant frequency. The difference between the first resonant frequency and the second resonant frequency is preferably such that there is little interference between the two resonant frequencies. As such, the frequency difference may be at least 1 MHz.

One, or each, independent rotation gate may further comprise a plurality of electrodes configured to position the qubit and wherein moving the qubit out of resonance comprises applying voltages to the electrodes to move the qubit.

The magnetic field may comprise a magnetic field gradient. This means that different lateral positions are subject to different magnetic fields and therefore have different resonant frequencies. Thus moving the qubit results in subjecting the qubit to a different magnetic field and therefore will become resonant at a different frequency.

The magnetic switch may comprise an electromagnet which allows it to be switched on and off easily. Additionally, the magnet, for generating a magnetic field, may comprise an electromagnet.

The magnet of one or all of the independent rotation gates may comprise a magnetic bypass configured to change the magnetic field at the qubit position and move the qubit out of resonance at a predetermined time wherein the controller is configured to control the magnetic bypass switch to change the magnetic field at the qubit position.

The magnet may comprise a current carrying wire and the magnetic bypass comprise a switch to change the path of the current through the wire. The switch may be a transistor.

The predetermined time may be a single period of the rabi frequency, thereby enabling a degree of rotation to be applied to the qubit.

According to another aspect of the invention there is provided a method of applying a rotation to a magnetically sensitive qubit. The method comprises generating a magnetic field at a qubit position, the magnetic field generating a resonant frequency at the qubit position, generating an electromagnetic field for a predetermined time at the resonant frequency for a predetermined period and moving the qubit out of resonance at a predetermined time within the predetermined period.

Moving the qubit out of resonance may comprise applying an additional magnetic field at the qubit position. Additionally, generating a magnetic field at a qubit position comprises generating a magnetic field gradient. If there is a magnetic field gradient, moving the qubit out of resonance comprises moving the qubit such that the resonant frequency of the qubit changes.

There is provided a device comprising a plurality of independent phase rotation gates, each phase rotation gate comprising a magnet configured to generate a magnetic field of predetermined strength at a qubit position for the respective rotation gate, the magnetic field configured to set a resonant frequency in a qubit at the qubit position due to magnetically sensitive electronic states of the qubit. Each independent phase rotation gate comprises a controller configured to independently move the qubit at the respective independent phase rotation gate out of resonance. The phase rotation is around the z axis.

The resonant frequency sets a “reference clock” and by moving the qubit out of the resonant frequency the phase of the qubit can be adjusted. For example, increasing the magnetic field would increase the angular frequency of the qubit and therefore increase the phase (relative to the “reference clock” frequency). Reducing the magnetic field would reduce the angular frequency of the qubit and therefore reduce the phase (relative to the “reference clock” frequency). Once the desired phase rotation relative to the reference clock frequency has been achieved the qubit can be moved back into resonance and thus resume rotation at the resonant frequency.

The controller may control the qubit to be moved out of resonance for a predetermined period and the qubit may then be moved back into resonance.

One, or each phase rotation gate may comprise a magnetic switch. The magnetic switch can be used to move the qubit out of resonance and thus adjust the phase of the qubit. The magnetic switch may comprise an electromagnet.

One, or each phase rotation gate may comprise a plurality of electrodes configured to position the qubit and wherein moving the qubit out of resonance comprises applying voltages to the electrodes to move the qubit. The magnetic field may comprise a magnetic field gradient and therefore moving the qubit changes the magnetic field to which the qubit is subjected. This changes the angular frequency and thus the phase relative to the “reference clock” frequency.

The magnet may comprise a magnetic bypass configured to change the magnetic field at the qubit position to move the qubit out of resonance. The magnet may comprise a current carrying wire and the magnetic bypass comprise a switch to change the path of current through the wire.

There may be a first qubit at a first phase rotation gate and a second qubit at second phase rotation gate. Different magnetic fields may be applied to each of the qubits to change their phases. In this way different phase rotations may be applied to different qubits within a larger scale processor.

According to the invention there is provided a method of applying independent rotations to a plurality of qubits at a plurality of qubit positions wherein the qubits having magnetically sensitive electronic states. The method comprises generating a magnetic field of predetermined strength at the qubit positions, the magnetic field setting a resonant frequency at the qubit positions due to magnetically sensitive electronic states of the qubits and moving a qubit, from the plurality of qubits, out of resonance. The qubit may be moved out of resonance for a predetermined period and may then be moved back into resonance.

Moving the qubit out of resonance may comprise applying an additional magnetic field at the qubit position. Generating a magnetic field of predetermined strength at a qubit position may comprise generating a magnetic field gradient. Moving the qubit out of resonance may comprise moving the qubit such that the resonant frequency of the qubit changes.

The magnetic field may be generated by a magnet comprising a magnetic bypass and moving the qubit out of resonance may comprise controlling the magnetic switch to change the magnetic field at the qubit position.

The magnet may comprise a current carrying wire and the magnetic bypass may comprises a switch to change the path of the current through the wire.

According to the invention there is a device comprising a quantum processor, a first electromagnetic field source configured to generate a first electromagnetic field at a first frequency and a second electromagnetic field source configured to generate a second electromagnetic field at a second frequency, different from the first frequency. The quantum processor comprises a switchable magnet having a first position generating a first magnetic field and a second position generating a second magnetic field; The quantum processor also comprises a magnetic structure configured to generate a magnetic field gradient in space, wherein, due to the magnetically sensitive electronic state of the qubit, with the switchable magnet in a first position, the magnetic field at a first position sets a resonant frequency of a qubit at the first position at the first frequency and the magnetic field at a second position sets a resonant frequency of a qubit at the second position at the second frequency. When the switchable magnet is in the second position a qubit at the first position has a resonant frequency at the second frequency.

According to the invention there is provided method of changing the resonant frequency of a qubit having a magnetically sensitive electronic state, the method comprising generating a magnetic field gradient in space wherein, due to the magnetically sensitive electronic state of the qubit, the magnetic field at a first position sets a resonant frequency of a qubit at the first position at a first frequency and the magnetic field at a second position sets a resonant frequency of a qubit at the second position at the second frequency. The method further comprises generating an additional magnetic field such that a qubit at the first position has a resonant frequency at the second frequency.

The additional magnetic field is an offset such that the gradient, or shape of the magnetic field remains the same, but is magnetically offset.

The magnetic field gradient may be linear or non-linear.

### BRIEF DESCRIPTION OF THE DRAWINGS

The invention will now be further and more particularly described, by way of example only, and with reference to the accompanying drawings, in which:

FIG. 1 depicts an arrangement of channels, in which gates occur, in a quantum computer;

FIG. 2 depicts a quantum gate;

FIG. 3 depicts an arrangement of a plurality of gates according to the invention;

FIG. 4 depicts an alternative quantum gate arrangement;

FIG. 5 depicts a magnetic field generation means according to the invention; and

FIG. 6a depicts an alternative quantum gate; and

FIG. 6b depicts an alternative quantum gate.

### DETAILED DESCRIPTION

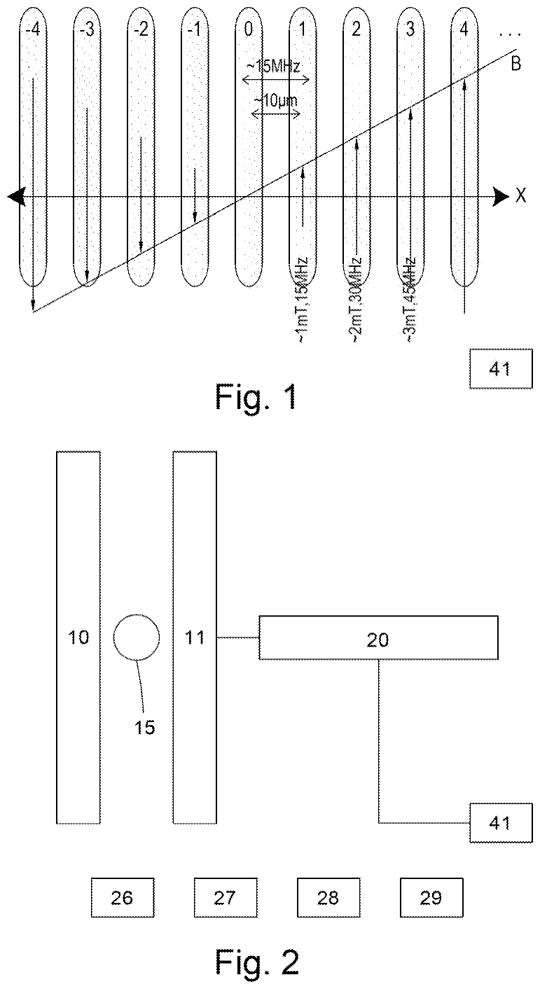

FIG. 1 depicts an arrangement of channels 1, 2, 3, 4 in a quantum computer. A magnetic field gradient has been applied and channels are formed at intervals of approximately 1 mT intervals and a distance of approximately 10 μm.

Using a Ytterbium ion as a qubit, there is hyperfine splitting between the 2S1/2 F=0 and F=1 manifolds of 12.64 GHz in the absence of a magnetic field. In addition, the frequencies of the F=1, mF=+/−1 states increase/decrease linearly with magnetic field due to the Zeeman effect. Various combinations of these states have been proposed to make qubits.

Each different magnetic field has a different energy level splitting, which can then be addressed using an electromagnetic field of different frequency. For example, a qubit in channel 1 can be addressed using a field of 15 MHz above the splitting frequency whereas a qubit in channel 2 can be addressed using a field of 30 MHz above the splitting frequency. Thus channels are addressed using different electromagnetic frequencies.

On a device there are a plurality of multi-channel areas, with each area having the same magnetic field gradient and arrangement of channels. Thus when an electromagnetic field of 30 MHz above the frequency splitting is applied to the device it is applied to all qubits in channel 2. Where there is a rotation gate, in which the rotation may be any value between 0 and 2π, depending on the duration of the electromagnetic field, the same rotation is applied to any qubits in channel 2 in any gates on the device if the magnetic field and position of the qubit remains the same.

FIG. 2 depicts a magnetic field structure (for example generated using current carrying wires) 10, 11 and a qubit 15 position in the magnetic field. The magnetic field, in this example is 2 mT which sets a resonant frequency of 30 MHz above the splitting frequency. A magnetic switch 20, comprising an electromagnet of a current carrying wire is positioned nearby.

There is an electromagnetic field source 26 configured to generate an electromagnetic field at +15 MHz above the splitting frequency. Similarly electromagnetic field sources 27, 28, 29, are each configured to generate a magnetic field at +30 MHz, +45 MHz and +60 MHz above the splitting frequency.

Electromagnetic field source 27 generates an electromagnetic field of duration 2π of the rabi frequency at a frequency of 30 MHz above the splitting frequency (+30 MHz) (to apply to channel 2). If the entire 2π electromagnetic field is applied to the qubit 15 a rotation of 2π will occur. However, at time π/2 (of the rabi frequency) a controller 41 switches the magnetic switch. This is achieved by applying a current to the magnetic switch 20. The magnetic switch increases the magnetic field at the qubit position thereby changing the resonance of the qubit. At the point π/2 (of the rabi frequency) the qubit will no longer be in resonance with the +30 MHz wave and therefore the rotation will cease. A rotation of π/2 , and no more, is therefore applied. Different rotations can be applied in this way. For example if a rotation of 4π/3 was required the magnetic switch could be switched on at 4π/3.

The magnetic field applied by the magnetic switch is sufficient to take it out of the resonant frequency. It may be sufficient just to take it out of the resonant frequency. Alternatively it could apply a magnetic field of 1 mT which would be sufficient to take the qubit into the next channel. If electromagnetic field source 28 (at +45 MHz) is generating an electromagnetic field then the qubit may be rotated according to the period of electromagnetic field source 28. For example, there may be additional rotation.

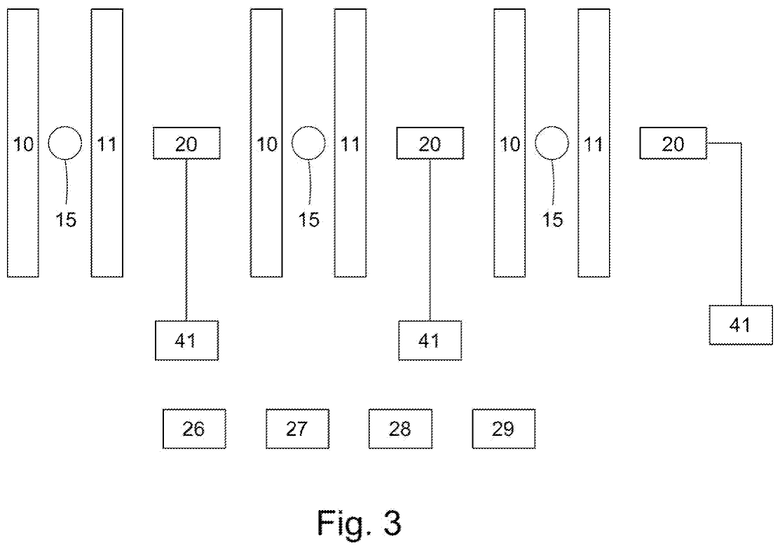

FIG. 3 depicts a plurality of gates on a device in which there are a plurality of qubits, each in the same channel i.e. having the same resonant frequency. As can be seen, there is a controller 41 for each gate. A global electromagnetic field is generated, at the resonant frequency (e.g. +30 MHz above the splitting frequency) for 2π. The controller 41 for each respective gate can switch each magnetic switch at a different time such that each qubit has a different rotation. For example one qubit can have a π/3 rotation, another a π/2, another 3π/2 etc. etc. Thus a single electromagnetic wave can be transmitted to all qubits in a channel 2 (i.e. all qubits which are resonant at 30 MHz) but different rotations applied to different qubits by using individual switches. Although this depicts a single controller for all qubit positions, a different controller could be used for each individual qubit position.

Although this embodiment is described using a magnetic field gradient, the magnetic switch could also be used in conjunction with a static (i.e. no gradient) magnetic field.

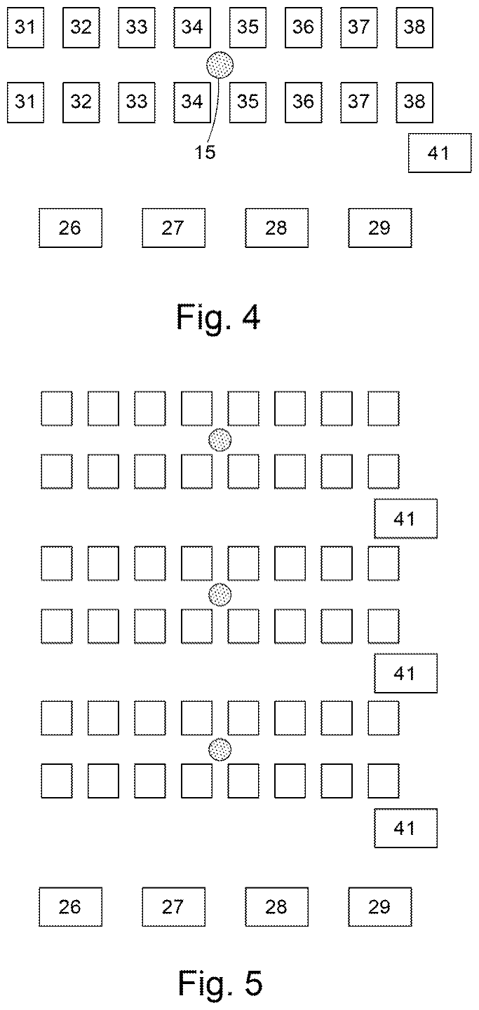

FIG. 4 depicts an arrangement of pairs of electrodes 31, 32, 33, 34, 35, 36, 37, 38, each connected to the controller 41. Voltages can be applied to the electrodes to move the qubit. For systems in which there is a magnetic field gradient moving the qubit changes the magnetic field to which the qubit is subjected and therefore the resonant frequency. Thus, with a qubit in channel 2, voltages could be applied to the electrodes, at a predetermined time during the +30 MHz electromagnetic field, to move the qubit 5 μm in an x direction. For example, the voltages could be applied at a time π/2 of the rabi frequency in the electromagnetic field. This would change the magnetic field the qubit is in and therefore the resonant frequency. Thus the qubit is subjected to only π/2 of the electromagnetic field and therefore a rotation of only π/2 of the rabi frequency applied.

Thus the rotation applied is equal to the period for which the electromagnetic pulse (at the resonant frequency) is applied multiplied by the rabi frequency of the ion.

FIG. 5 depicts three identical gates on a device, each gate arrangement being similar to that depicted in FIG. 4 and each gate having its own controller 41. Similarly to FIG. 3 described above, different rotations can be applied to each different qubit position by moving the respective qubit for each gate independently.

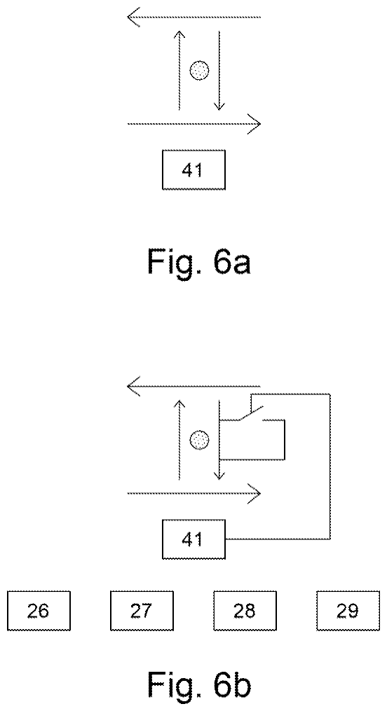

FIG. 6a depicts a conventional arrangement for current carrying wires to generate a magnetic field gradient used in conjunction with the arrangement of FIGS. 1 to 4. However, FIG. 6b depicts an alternative current carrying wire arrangement in which there is a bypass which can be used as an alternative way to move the qubit out of resonance. The bypass comprises a switch in to an alternative current path. Modifying the current path will change the magnetic field and so change the resonant frequency of the qubit. At a predetermined time in the electromagnetic field, controlled by the controller 41 the switch is switched and the current takes a different path.

As will be appreciated, there may be many gates on a device, each with a bypass arrangement as depicted in FIG. 6b.

The rotation described above is around the x or y axis, where the z axis is parallel to the magnetic field generated by the magnet. The relative rotation axis between one electromagnetic pulse generated by the electromagnetic field source and another electromagnetic pulse can be changed by adjusting the pulse phase.

Although the z axis is defined by the magnetic field the x and y axes are relative and aren't defined until the first rotation is performed (by the first electromagnetic pulse). Thereafter, all subsequent rotations are relative to this. For example if a second electromagnetic pulse has a phase of π/2 relative to the first (based on the resonant frequency) the second rotation would be around the y axis. For example, for a single frequency pulse of the form A(t)* sin (w*t+Φ) where w is the resonant (or angular) frequency, t is time and @ is the pulse phase the rotation axis is given by cos Φ*x+ sin Φ*y.

The magnetic field generated by the magnet sets a resonant, reference frequency for the qubit. Thus, if the magnetic field to which the qubit is subjected changes the angular rotation of the qubit changes. Thus the speed of angular rotation can be increased relative to the reference frequency or decreased relative to the reference frequency. This results in a phase change relative to the reference frequency. For example, an increase in magnetic field, resulting in an increase in angular frequency results in an increase in phase relative to the reference frequency. A decrease in magnetic field, resulting in a decrease in angular frequency results in a decrease in phase relative to the clock frequency.

The qubit can be moved out of resonance for a predetermined period, which generates a phase change relative to the reference frequency. As will be described the method and apparatus of moving the qubit out of resonance depicted in FIGS. 2, 3, 4, 5 and 6b can all be used to move the qubit out of resonance for a predetermined period. As will be appreciated by the skilled person, electromagnetic field sources 26, 27, 28 and 29 are not needed for the phase rotation.

The qubit can be moved out of resonance to a second resonant frequency for a predetermined period. The phase difference will be generated by the difference in rotations between the two resonant frequencies over the predetermined period. Thus, a specific phase difference can be induced.

As depicted in FIG. 2, a resonant frequency at a qubit position is set by the magnetic field structure(s) 10, 11 and a controller 41 controls a magnetic switch. The magnetic switch increases the magnetic field at the qubit position such that the angular rotation is increased and therefore the phase of the qubit is increased relative to the reference frequency. The qubit is moved out of resonance only for a predetermined time to achieve the desired rotation relative to the reference frequency.

Although the magnetic switch 20 is described as increasing the magnetic field it could equally decrease the magnetic field strength and the qubit position.

FIG. 3 depicts a plurality of gates, each with a controller and a magnetic switch such that the phase rotation of individual qubits can be controlled.

FIGS. 4 and 5 depict an arrangement in which each gate comprises a plurality of electrodes. In this example the magnetic field structure generates a magnetic field gradient and different voltages applied to the electrodes move the qubit such that the magnetic field gradient to which the qubit is subjected as changed. The qubit is moved out of resonance for a predetermined time, to generate a predetermined phase difference relative to the clock of the original resonant frequency, and then returned to resonance to resume angular rotation at the angular (or resonant) frequency.

FIG. 6b depicts a magnetic bypass which can be used to change the magnetic field at the qubit to move the qubit out of resonance for a predetermined period to induce a phase difference.

The methods for moving the qubit out of resonance depicted in FIGS. 2, 3, 4, 5, and 6b can be used independently of each or alternatively in combination. For example, both the magnetic field and the position of the qubit could be changed.

Although the invention describes the use of a separate magnet for each gate an alternative would be a single magnetic structure across a plurality of gates which generates the predetermined magnetic field at the qubit position of all of the gates.

Although the invention describes the use of a controller for each gate the skilled person would appreciate that a single controller could be used to control all of the gates independently.

Although the values here are illustrative, different spacings, both physically and magnetically, between the channels may be used.

FIG. 1 depicts a magnetic field gradient with a plurality of channels. As has been described, an additional magnetic field may be applied to the area as a whole. This would have the effect of increasing or decreasing the magnetic field across the whole area although the overall shape, or gradient of the magnetic field would remain the same. There would be an offset from the magnetic field depicted in FIG. 1. If the additional magnetic field applied was 1 mT then a qubit which was originally in channel I would be in channel 2 (because the total magnetic field to which the qubit is subjected is 2 mT). Similarly, a qubit previously in channel 2 would be in channel 3. In this way it is possible to move qubits between channels without moving the qubits in space.

The linear distance between different channels may be at least 500 nm and they may have a frequency difference of at least 1 MHz.

Applying an additional, offset, magnetic field could be achieved using the magnetic switch in FIG. 2. Alternatively, a magnetic bypass (unrelated to the magnetic structure used to generate the magnetic field gradient) could be used. With the bypass, or switch, in a first position there is a first global magnetic field, or offset, and a qubit may be in a first channel. The first global magnetic field, or offset, may be zero but may be non-zero. However, with the bypass, or switch, in a second position there is a second global magnetic field, or offset and the qubit may be (without moving in space) in a second channel due to the change in the global magnetic field, or offset. This method may be used to move a qubit between adjacent channels or even non-adjacent channels.

The magnetic field gradient depicted in FIG. 1 is linear. However, it may not be linear: it could be quadratic or take a square shape.

The invention has been described in combination with single qubit gates but could equally well apply to two or more qubit gates.

Various further aspects and embodiments of the present invention will be apparent to those skilled in the art in view of the present disclosure.

“and/or” where used herein is to be taken as specific disclosure of each of the two specified features or components with or without the other. For example “A and/or B” is to be taken as specific disclosure of each of (i) A, (ii) B and (iii) A and B, just as if each is set out individually herein.

Unless context dictates otherwise, the descriptions and definitions of the features set out above are not limited to any particular aspect or embodiment of the invention and apply equally to all aspects and embodiments which are described.

It will further be appreciated by those skilled in the art that although the invention has been described by way of example with reference to several embodiments. It is not limited to the disclosed embodiments and that alternative embodiments could be constructed without departing from the scope of the invention as defined in the appended claims.

1.-20. (canceled)

21. A device comprising:
a plurality of independent phase rotation gates, each phase rotation gate comprising:
a magnetic structure configured to generate a magnetic field of predetermined strength at a qubit position for the respective rotation gate, wherein the magnetic field is configured to set a resonant frequency in a qubit at the qubit position based at least in part on magnetically sensitive electronic states of the qubit; and
a controller configured to independently shift the qubit at the respective independent rotation gate out of resonance for a predetermined period.

22. The device of claim 21, wherein the device further comprises: a first electromagnetic field source configured to generate an electromagnetic field at the resonant frequency for a predetermined period across the plurality of independent rotation gates.

23. The device of claim 21, wherein each independent rotation gate further comprises a magnetic switch controlled by the controller and configured to adjust the magnetic field at the qubit position.

24. The device of claim 23, wherein the magnetic switch when actuated is configured to shift the qubit out of resonance.

25. The device of claim 23, wherein the magnetic switch comprises an electromagnet.

26. The device of claim 21, wherein the combined magnetic field of predetermined strength and the magnetic field generates a second resonant frequency, and wherein the device further comprises a second electromagnetic field source configured to generate an electromagnetic field at the second resonant frequency.

27. The device of claim 26, wherein the frequency difference between the first and second electromagnetic fields is at least 1 MHz.

28. The device of claim 21, wherein the independent rotation gate further comprises a plurality of electrodes configured to position the qubit and wherein the controller is configured to apply voltages to the electrodes to shift the qubit.

29. The device of claim 21, wherein the magnetic field comprises a magnetic field gradient.

30. The device of claim 21, wherein the magnetic field gradient is linear or non-linear.

31. The device of claim 21, wherein the magnetic structure comprises an electromagnet.

32. The device of claim 21, wherein the magnetic structure comprises a magnetic bypass configured to change the magnetic field at the qubit position and shift the qubit out of resonance at a predetermined time wherein the controller is configured to control the magnetic bypass switch to change the magnetic field at the qubit position.

33. The device of claim 32, wherein the magnetic structure comprises a current carrying wire and the magnetic bypass comprises a switch to change the path of the current through the wire.

34. The device of claim 21, wherein the predetermined time is a single period of the resonant frequency.

35. The device of claim 21, wherein the device further comprises a first qubit at a first rotation gate and a second qubit at a second rotation gate.

36. The device of claim 21, wherein the magnetic structure comprises a current carrying wire.

37. The device of claim 36, wherein the magnetic structure comprises a switch, wherein the switch is configured to change the path of the current through the wire.

38. The device of claim 37, wherein the switch is a transistor.

39. The device of claim 21, wherein the predetermined time is based at least in part on a rabi frequency.

40. A method of applying independent phase rotation gates, the method comprising:
(a) providing a plurality of qubits at a plurality of qubit positions, wherein the qubits have magnetically sensitive electronic states;
(b) generating a magnetic field of predetermined strength at a qubit position of the plurality of qubit positions, wherein the magnetic field is configured to set a resonant frequency at the qubit position based at least in part on the magnetically sensitive electronic states of the plurality of qubits; and
(c) shifting a qubit of the plurality of qubits at the qubit position out of resonance for a predetermined period, thereby applying a phase rotation to the qubit.
